(19) United States
(12) Patent Application Publication
(10) Pub. No.: US 2010/0139621 A1
(43) Pub. Date: Jun. 10, 2010

(54) STACKED PIEZOELECTRIC DEVICE

(75) Inventors: Atsushi Murai, Kuwana-shi (JP); Satoshi Suzuki, Nisshin-shi (JP); Toshiatu Nagaya, Kuwana-shi (JP); Akio Iwase, Nishio-shi (JP); Akira Fujii, Yokkaichi-shi (JP); Shige Kadotani, Chita-gun (JP)

Correspondence Address: NIXON & VANDERHYE, PC, 901 NORTH GLEBE ROAD, 11TH FLOOR, ARLINGTON, VA, 22203, US

(73) Assignee: DENSO CORPORATION, Kariya-city, Aichi-pref (JP)

(21) Appl. No.: 12/528,677

(22) PCT Filed: Feb. 26, 2008
(86) PCT No.: PCT/JP2008/053228

§ 371 Date: Feb. 2, 2010

(30) Foreign Application Priority Data
Feb. 26, 2007 (JP) 2007-046071
Feb. 22, 2008 (JP) 2008-042112

(51) Int. Cl. F02M 51/00; H01L 41/083; H01L 41/24; H01L 41/047

(52) U.S. Cl. 123/472; 310/367; 29/25.35; 310/366

(57) ABSTRACT

A stacked piezoelectric device 1 includes a ceramic laminate 15 formed by laminating a plurality of piezoelectric ceramic layers 11 and a plurality of inner electrode layers 13 and 14 alternately and a pair of side electrodes 17 and 18 formed on side surfaces thereof. The inner electrode layers 13 and 14 are connected electrically to either of the side electrodes. The ceramic laminate 15 has absorbing portions 12 formed in slit-like areas recessed inwardly from the side surfaces thereof. The stress absorbing portions are easier to deform than the piezoelectric ceramic layers 11. Adjacent two of the inner electrode layers 13 and 14 interleaving the stress absorbing portion 12 therebetween are both connected electrically to the positive side electrode 17.

### TECHNICAL FIELD

The present invention relates to a stacked piezoelectric device equipped with a ceramic laminate made up of a plurality of piezoelectric ceramic layers and a plurality of inner electrode layers which are laminated alternately, a pair of side electrodes formed on side surfaces of the ceramic layer laminate, and stress absorbing portions formed in slit-like areas depressed inwardly into the sides of the ceramic laminate.

### BACKGROUND ART

Conventionally, stacked piezoelectric devices are used as drive source of fuel injectors. The stacked piezoelectric device is made up of for example, a ceramic laminate formed by stacking inner electrodes and piezoelectric ceramics alternately and a pair of outer electrodes connected to the inner electrode alternately.

The stacked piezoelectric device is used in severe environmental conditions over a long duration, especially when employed in fuel injectors. Therefore, in order to improve the electric insulation of the side surfaces, a ceramic laminate having inner electrode-unformed areas where a portion of an end of an inner electrode layer is recessed inwardly is adapted widely.

However, the formation of the inner electrode-unformed areas in order to improve the insulation may cause portions which are susceptible and insusceptible to deformation to appear in the ceramic laminate upon application of voltage thereto, resulting in concentration of stress at interfaces therebetween and cracks in the device.

In order to avoid the cracks arising from the concentration of stress, stacked piezoelectric devices are being developed which have grooves (stress absorbing portions) formed at a given interval away from each other in a laminating direction in the side surface of the ceramic laminate (see patent document 1).

However, even when the stress absorbing portions are formed, the application of the voltage to the stress absorbing portions also may result in cracks extending from the top end of the stress absorbing portions. In order to avoid this, it is necessary to increase the depth of the stress absorbing portion in a direction perpendicular to the laminating direction more than the distance of the inner electrode-unformed areas. Such a structure, however, causes great electric discharge to occur at the stress absorbing portions (grooves) upon application of great voltage thereto, so that they may be short-circuited. This gives rise to the problem of insufficient electric insulation, which results in a decrease in service life of the stacked piezoelectric devices.

Stacked piezoelectric devices are being developed in which the inner electrodes interleaving the stress absorbing portion therebetween are made to have the same polarity in order to avoid the formation of cracks (see patent document 2). In such conventional stacked piezoelectric devices, it is possible to make the inner electrodes interleaving the stress absorbing portion therebetween to have the same polarity to make the piezoelectric ceramic layer interleaved between them as voltage inactive layers, thereby concentrating the stress at the voltage inactive layers when the stacked piezoelectric device expands. This causes cracks to occur in the stress absorbing portions selectively or preferentially, thereby avoiding the crack in voltage active layers of the laminate to improve the durability.

### DISCLOSURE OF THE INVENTION

### Problems to be Solved by the Invention

When two of the inner electrode layers interleaving the stress absorbing portion, as described above, are designed to have the same polarity, it will cause cracks to occur in the stress absorbing portions selectively or preferentially. It is, therefore, possible to avoid the occurrence of cracks in the piezoelectric active layers of the stacked piezoelectric device and improve the durability.

However, in fact, even when no cracks occur in the stress absorbing portions, it is still difficult to ensure sufficient electric insulation, which gives rise to the problem of a drop in electric insulation, thus resulting in an electric short.

Patent Document 1: Japanese patent first publication No 62-271478

Patent Document 2: Japanese patent first publication No. 2006-216850

The present invention was made in view of the above problem and is to provide a stacked piezoelectric device designed to avoid a drop in insulation resistance surely to show an excellent durability.

### Means for Solving Problem

The invention lies at a stacked piezoelectric device including a ceramic laminate formed by laminating a plurality of piezoelectric ceramic layers and a plurality of inner electrode layers alternately and a pair of side electrodes formed on side surfaces of the ceramic laminate, characterized in that said inner electrode layers are connected electrically to either of the side electrodes, said ceramic laminate has stress absorbing portions formed in slit-like areas recessed inwardly from the side surfaces thereof, the stress absorbing portions being easier to deform than said piezoelectric ceramic layers, and adjacent two of said inner electrode layers interleaving the stress absorbing portion therebetween are both connected electrically to a positive side of the side electrodes (claim 1).

The most notable point of the invention is that adjacent two of said inner electrode layers interleaving the stress absorbing portion therebetween are both connected electrically to the positive side of the side electrodes.

Specifically, the inventors of this invention have studied the disadvantages arising from the formation of the stress absorbing portions such as grooves in the stacked piezoelectric device and found that the piezoelectric ceramic layers interleaved between a negative electrode layer next to the stress absorbing portion and a positive electrode layer next to the negative electrode layer will drop in insulation resistance earliest.

First, a drop in insulation resistance of typical stacked piezoelectric devices will be discussed below for explaining the details of the above.

Generally, when high electric field continues to be applied to the stacked piezoelectric device at a high temperature, the phenomenon that a lower resistance area spreads from the negative electrode side will appear. For example, the cause is that when the stacked piezoelectric device is made integrally by the firing, conductive metallic ions, as spreading to the piezoelectric ceramic layers during the firing, are metalized by electrons emitted from the negative electrode. The above phenomenon results in a variation in distribution of electric field intensity oriented in the laminating direction between the positive electrode layer and the negative electrode layer. In other words, the electric field intensity drops in the low resistance area, thereby resulting in a rise in electric field intensity in areas other than the low resistance area. The rise in electric field intensity accelerates the deterioration of the insulation resistance. The spreading of the low resistance area is usually accelerated by the existence of water.

Specifically, the phenomenon occurs that Ag⁺ ions, as spreading from an inner electrode-formed areas made with an AgPd electrode to piezoelectric ceramic layers made of PZT when the piezoelectric device is being fired as a whole are metalized by electrons emitted from the negative electrode layers during driving of the piezoelectric device, thereby causing the low resistance area to be formed which, in turn, expands to the positive electrode layer (Ag⁺+e⁻→Ag metal).

Particularly, in the case where the stacked piezoelectric device with the stress absorbing portions, the stress absorbing portions will usually be a path leading to the outside where water exists. The phenomenon that the low resistance area expands in the negative electrode layer closest to the stress absorbing portion, therefore, becomes pronounced.

Accordingly, the piezoelectric ceramic layer interleaved between the negative electrode layer next to the stress absorbing portion and the positive electrode layer next to the negative electrode layer drops in insulation resistance earliest. The drop in insulation resistance tends to occur in the case where at least one of adjacent two of the inner electrode layers interleaving the stress absorbing portion therebetween is at the negative polarity. The drop in insulation resistance is usually taken place between the inner electrode layer of the negative polarity and the adjacent inner electrode layer of the positive polarity, which may result in an electric short.

Specifically, the drop in insulation resistance tends to occur in the case where at least one of adjacent two of the inner electrode layers interleaving the stress absorbing portion therebetween is at the negative polarity. The drop in insulation resistance is usually taken place between the inner electrode layer of the negative polarity and the adjacent inner electrode layer of the positive polarity, which may result in an electric short.

When adjacent two of the inner electrode layers interleaving the stress absorbing portion therebetween are, like in the invention, both at the positive polarity, it will result in no inner electrode layers interleaving the stress absorbing portions therebetween which contribute to the drop in insulation resistance, thus avoiding the drop in insulation resistance and improving the durability of the stacked piezoelectric device.

The positive electrode layers and the negative electrode layers, as referred to above, are the inner electrode layers connected electrically to the positive and negative sides of the side electrodes, respectively.

### BRIEF DESCRIPTION OF THE DRAWINGS

FIG. 1 is an explanatory view which shows the structure of a stacked piezoelectric device according to the embodiment 1;

FIG. 2 is a cross sectional view of a stacked piezoelectric device (ceramic laminate) according to the embodiment 1;

FIG. 3 is an explanatory view which shows a process of forming a first electrode-printed sheet according to the embodiment 1;

FIG. 4 is an explanatory view which shows a process of forming a second electrode-printed sheet according to the embodiment 1;

FIG. 5 is an explanatory view which shows a process of forming a burn-off slit-printed sheet according to the embodiment 1;

FIG. 6 is an explanatory view which shows a process of stacking electrode-printed sheets and burn-off slit-printed sheets according to the embodiment 1;

FIG. 7 is a top surface view of a pre-laminate according to the embodiment 1;

FIG. 8 is a cross sectional view showing an A-A sectional area in FIG. 5;

FIG. 9 is an explanatory view which shows a sectional structure of an intermediate laminate according to the embodiment 1;

FIG. 10 is a schematic view of a sectional structure of a stacked piezoelectric device (sample E1) according to the embodiment 1;

FIG. 11 is a schematic view of a sectional structure of a stacked piezoelectric device (sample Ca1) according to the embodiment 1;

FIG. 12 is a schematic view of a sectional structure of a stacked piezoelectric device (sample Cb1) according to the embodiment 1;

FIG. 13 is a schematic view of a sectional structure of a stacked piezoelectric device (sample E2) according to the embodiment 1;

FIG. 14 is a schematic view of a sectional structure of a stacked piezoelectric device (sample Ca2) according to the embodiment 1;

FIG. 15 is a schematic view of a sectional structure of a stacked piezoelectric device (sample Cb1) according to the embodiment 1;

FIG. 16 is a schematic view of a sectional structure of a stacked piezoelectric device (sample E3) according to the embodiment 1;

FIG. 17 is a schematic view of a sectional structure of a stacked piezoelectric device (sample Ca3) according to the embodiment 1;

FIG. 18 is a schematic view of a sectional structure of a stacked piezoelectric device (sample Cb3) according to the embodiment 1;

FIG. 19 is an explanatory view which shows the durability of nine types of stacked piezoelectric devices made in the embodiment 1;

FIG. 20 is an explanatory view which shows a mode in which ceramic laminates are bonded to make a stacked piezoelectric device;

FIG. 21 is an explanatory view which shows a sectional structure of a stacked piezoelectric device made by bonding ceramic laminates;

FIG. 22 is a development view of a ceramic laminate which shows a pattern in which inner electrode portions and slit layers are formed according to the embodiment 1; and

FIG. 23 is an explanatory view which shows variations (a) to (c) of a pattern in which inner electrode portions and slit layers are formed according to the embodiment 1.

DESCRIPTION OF REFERENCE NUMBERS

| | |
|---|---|
| 1 | stacked piezoelectric device |
| 11 | piezoelectric ceramic layer |
| 12 | stress absorbing portion |
| 13 | inner electrode layer |
| 14 | inner electrode layer |
| 15 | ceramic laminate |
| 17 | side electrode |
| 18 | side electrode |

### BEST MODES OF THE INVENTION

Next, a preferred embodiment of the invention will be described.

The stacked piezoelectric device of the invention is equipped with the ceramic laminate and a pair of side electrodes formed on the side surfaces of the ceramic laminate.

The ceramic laminate is made by stacking the piezoelectric ceramic layers and the inner electric layers alternately. The ceramic laminate has the stress absorbing portion in the slit-like areas recessed inwardly from the side surfaces of the ceramic laminate.

The stress absorbing portions are portions of the ceramic laminate where crystalline particles making up the piezoelectric ceramic are separated in the laminating direction and which are easier to deform in shape than the piezoelectric ceramic layers.

The stress absorbing portions work to absorb the stress accumulated in the laminating direction of the ceramic laminate. When the stacked number is small, it will result in a decrease in ability of the stress absorbing portions to absorb the stress. It is, therefore, preferable that the stacked piezoelectric device has the twenty or more inner electrode layers. For the same reasons, the interval between the stress absorbing portions in the laminating direction is preferably greater than or equal to the ten inner electrode layers and smaller than or equal to the fifty inner electrode layers. When the interval between the stress absorbing portions is less than the ten inner electrode layers or greater than the fifty inner electrode layers, it may result in a lack in stress absorbing ability of the stress absorbing portions.

Specifically, the stress absorbing portions are, for example, slit-like chambers (grooves) and may be of a structure wherein the slit-like chamber is filed with resin material which is lower in Young's modulus than the piezoelectric ceramic layer, slit-like fragile layers formed by making the same material as the piezoelectric ceramic layer to be porous, slit-like fragile layers made by material such as titanate different from that of the piezoelectric ceramic layer, or crack-like slits made intentionally by the polarization or actuation.

The stress absorbing portions are preferably slit-like grooves recessed inwardly from the side surface of the ceramic laminate (claim 2).

This facilitates the formation of the stress absorbing portions.

The stress absorbing portions are formed in the side surfaces of the ceramic laminate. The stress absorbing portions may be partially formed in the side surfaces on which the side electrodes are disposed. In this case, it is preferable that a pair of the stress absorbing portions are formed which interleave the side surfaces of the ceramic laminate therebetween. The stress absorbing portions may also be formed so as to extend in the entire peripheral surface in a circumferential direction.

The stacked piezoelectric device is preferably made by firing the plurality of piezoelectric ceramic layers and the plurality of inner electrode layers integrally (claim 3).

In this case, as compared with when a stacked piezoelectric device made by bonding laminates, as described later, by adhesive, it is possible to improve the amount of displacement and to make the stacked piezoelectric device more easily.

The stacked piezoelectric device is preferably made by bonding a plurality of the ceramic laminates through adhesive in a laminating direction (claim 4).

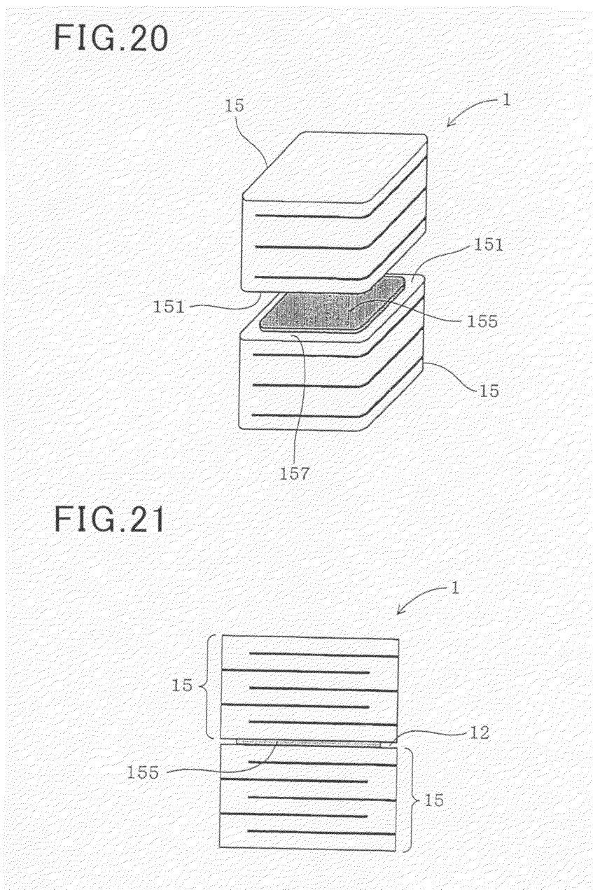

In this case, as illustrated 1 FIGS. 20 and 21, the stacked piezoelectric device 1 which is relatively greater in stacked number may be made by joining ceramic laminates 15 together which are relatively smaller in stacked number. This facilitates ease of dewaxing and firing the stacked piezoelectric device when manufactured and produces the stacked piezoelectric device easily which is small in variation in amount of displacement.

The stress absorbing portions are preferably formed by providing non-bonding portions to which no adhesive is applied near an outer periphery of the ceramic laminates when the ceramic laminates are joined together through the adhesive (claim 5).

This facilitates the formation of the stress absorbing portions.

Specifically, as illustrated in FIGS. 20 and 21, when the two or more ceramic laminates 15 are joined at joining surfaces 151 together using adhesive 155 to make the stacked piezoelectric device 1, the adhesive 155 is applied to a central portion of the joining surface 151 of the laminates 15 so as to provide a non-joining portion 157 to which no adhesive is applied near the outer periphery of the joining surface 151 of the laminate 15. The ceramic laminates 15 are joined in this way to make the slit-like groove (i.e., the stress absorbing portion) 12 easily around the adhesive layer 155 through the non-joining portion. In this case, the drop in insulation resistance is avoided by connecting adjacent two of the inner electrode layers interleaving the stress absorbing portion therebetween made by the non-joining portion to the positive side of the side electrodes. This exhibits the operation and effect of the invention that the durability is good.

The stress absorbing portions are preferably made using burn-off material which will be burnt off in the firing process (claim 6).

As the burn-off material, powder-like carbon particles, resinous particles, or carbonized organic particles made by carbonizing organic powders may be used.

Particularly, when the carbon particles are used as the burn-off material, the stress absorbing portions are shaped accurately because the carbon particles are insusceptible to thermal deformation.

Particularly, when the carbonized organic particles are used as burn-off material, it will result in a decrease in production cost of the stress absorbing portions.

The use of the carbonized organic particles as the burn-off material will result in a decrease in production cost required to form the stress absorbing portions.

As the organic particles, there are particles made by grinding soya beans, Indian corns, resinous material.

The carbonized organic particles, as referred to herein, are fine or minute particles made by removing water contained in organic particles partially to carbonize them to the extent that the flowability and dispersibility are good.

The stress absorbing portions are preferably made by forming the slit-like areas by material which causes cracks to occur when the stacked piezoelectric device is polarized or actuated and cracking the slit-like areas when the stacked piezoelectric device is polarized or actuated (claim 7).

This also facilitates the formation of the stress absorbing portions.

Two of the inner electrode layers which are located most outward of the stacked piezoelectric device in a laminating direction are preferably both connected to a positive side of the side electrodes (claim 8).

This improves the durability of the stacked piezoelectric device further.

In the case where the stacked piezoelectric device has the integrally formed signal ceramic laminate, two of the inner electrode layers which are located most outwardly of the ceramic laminate are preferably connected to the positive side of the side electrodes. In the case where the stacked piezoelectric device is made by bonding the plurality of ceramic laminates, two of the inner electrode layers located most outward of the bonded ceramic laminate are preferably connected to the positive side of the side electrodes.

The stacked piezoelectric device is preferably used in a fuel injector (claim 9).

In this case, the stability of operation of the stacked piezoelectric device in heavy environmental conditions is ensured for an increased time.

### EMBODIMENTS

### Embodiment 1

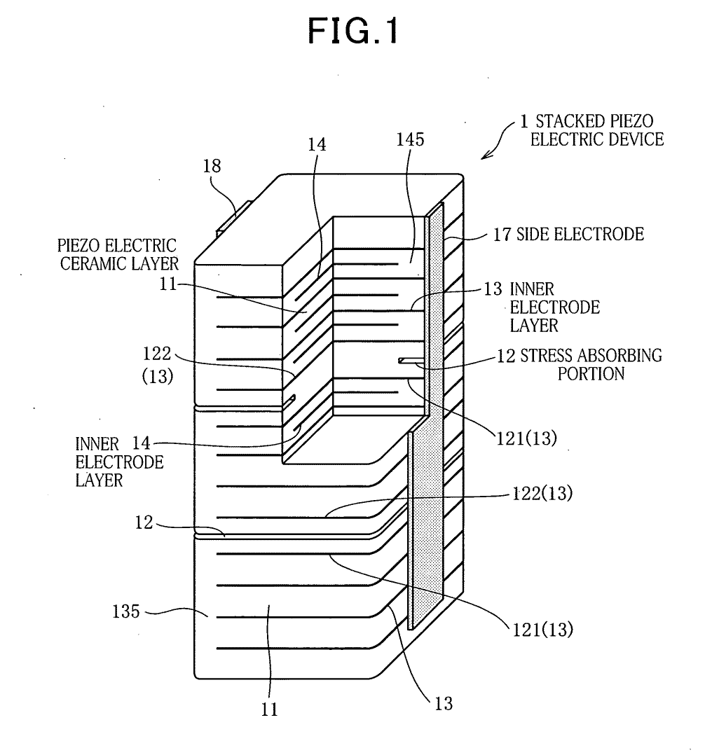

Next, the stacked piezoelectric device according to embodiments of the invention will be described below using FIGS. 1 to 20.

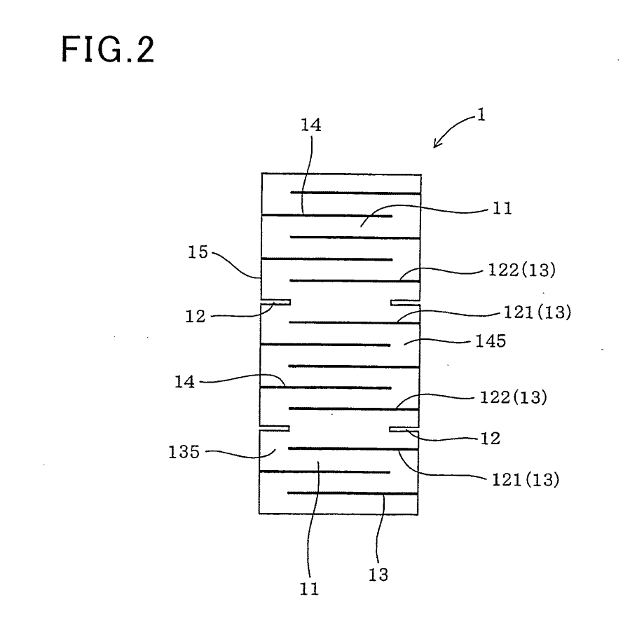

As illustrated in FIGS. 1 and 2, the stacked piezoelectric device 1 of this embodiment has a ceramic laminate 15 made by stacking the plurality of piezoelectric ceramic layers 11 and the plurality of inner electrode layers 13 and 14 alternately and the pair of side electrodes 17 and 18 formed on side surfaces of the ceramic laminate 15. The inner electrode layers 13 and 14 are connected to either of the side electrodes 17 and 18.

The ceramic laminate 15 has the stress absorbing portions 12 which are easier to deform in shape than the piezoelectric ceramic layers 11 in slit-like areas recessed inwardly from the side surfaces of the ceramic laminate 15. Adjacent two of the inner electrode layers 121 and 122 interleaving the stress absorbing portion 12 are both connected electrically to the positive side electrode 17. The remaining inner electrode layers 13 and 14 are connected electrically to the side electrodes 17 and 18 alternately.

The stress absorbing portions 12 of this embodiment are slit-like grooves (chambers) recessed inwardly from the side surface of the ceramic laminate 15. The stress absorbing portions 12 extend in the whole of the outer peripheral surface of the ceramic laminate 15 in a circumferential direction.

Next, a production method of the stacked piezoelectric device of this embodiment will be described below using FIGS. 1 to 9.

In this embodiment, the stacked piezoelectric device is made by a green sheet making process, an electrode printing process, an burn-out slit printing process, a pressure bonding process, a stack cutting process, and a firing process.

Next, each process of the production method will be described below.

<Green Sheet Making Process>

First, we prepared ceramic raw material powder such as lead zirconate titanate (PZT) which is a piezoelectric material. Specifically, we prepared Pb₃O₄, SrCO₃, ZrO₂, TiO₂, Y₂O₃, and Nb₂O₅ as starting raw materials, weighted them at a stoichiometric proportion which was selected to produce a target composition PbZrO₃—PbTiO₃—Pb(Y1/2Nb1/2)O₃, wet-blended, and calcined them at 850° C. for 5 hours. Next, we wet-ground the calcined powders using a pearl mill. We dried the calcined ground powders (Grain Size (D50): 0.7±0.05 μm) and blended with solvent, binder, plasticizer, and dispersant in a ball mill to make slurry. We agitated, vacuum-degassed, and adjusted the slurry in viscosity.

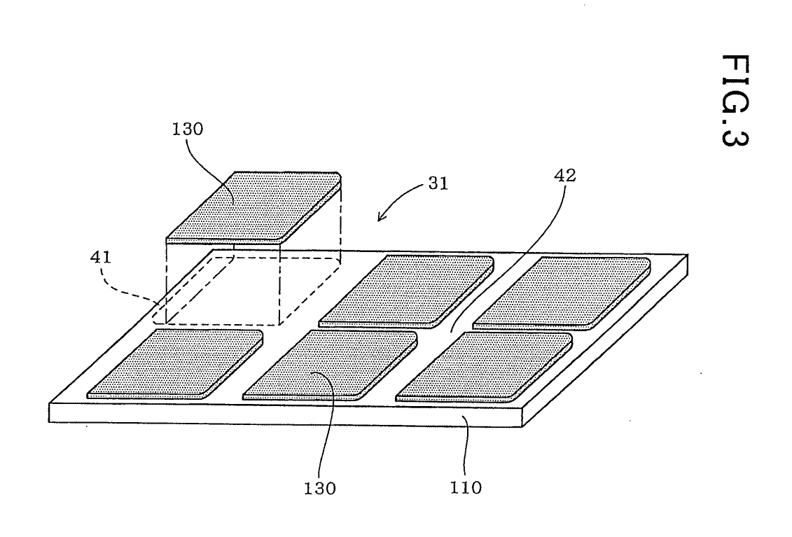

We applied the slurry on a carrier film using the doctor blade method to make elongated green sheet having a thickness of 80 μm. We cut the green sheet into a desired size to make wide green sheet 110, as illustrated in FIGS. 3 to 5.

The formation of the green sheet may alternatively be achieved by the extrusion molding or any other manners as well as the doctor blade method.

<Electrode Printing Process>

Next, as illustrated in FIGS. 3 and 4, electrode materials 130 and 140 which will be the inner electrode layers were printed on the green sheet 110. We formed two types of sheet: first electrode-printed sheet 31 and second electrode-printed sheet 32.

The formation of the electrode-printed sheets 31 and 32 will be described below in more detail.

The first electrode-printed sheet 31 was formed, as illustrated in FIG. 3, by printing the electrode material 130 on a section of each of printing areas 41 of the green sheet 110 which will finally be the inner electrode layer 13.

The second electrode-printed sheet 41 was, like the first electrode-printed sheet, formed by, as illustrated in FIG. 4, printing the electrode material 140 on a section of each of printing areas 41 of the green sheet 110 which will finally be the inner electrode layer 14.

In the first and second electrode-printed sheets 31 and 32, the electrode materials 130 and 140 formed on the green sheets 110 are exposed to side surfaces different from each other.

In this embodiment, Ag/Pd alloy paste was used as the electrode materials 130 and 140, Ag, Pd, Cu, Ni, or Cu/Ni alloy may alternatively be used.

<Burn-Out Slit Printing Process>

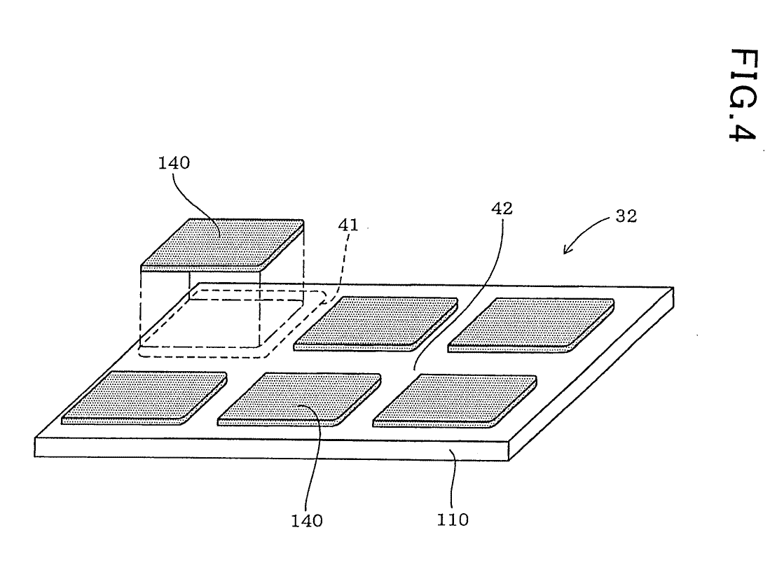

In this embodiment, slits 12 (see FIGS. 1 and 2) are formed in the side surfaces of the ceramic laminate 15 of the stacked piezoelectric device 1 to be manufactured. The burn-off slit printing process, as illustrated in FIG. 5, was made to form the burn-off slit-printed sheet 33.

As illustrated in FIG. 5, the burn-off slit layer 120 was formed by a burn-off material which is to be fired, so that it will be burnt off, on each printing area 41 of the green sheet 110, thereby forming the burn-off slit-printed sheet 33.

In this embodiment, carbon powder material which is small in thermal deformation and will keep the shape of grooves to be formed by the firing process precisely was used as the burn-off material to make the burn-off slit layer 120. Carbonized organic particles may alternatively be used. The carbonized organic particles may be made by carbonizing powder-like organic particles or grinding carbonized organic substance. As the organic substance, cereal grains such as cones, soya beans, or flour may be used to save the production costs.

In the electrode printing and burn-off slit printing processes, as illustrated in FIGS. 3 to 5, the electrode material 130 and 140 and the burn-off slit layers 120 are printed so that they are located away from each other through air gaps 42 where portions of the green sheet 110 are to be cut in the following unit cutting process. Specifically, the printing is made to have the air gaps 42 between the adjacent printing areas 41 on the green sheet 110.

<Pressure Bonding Process>

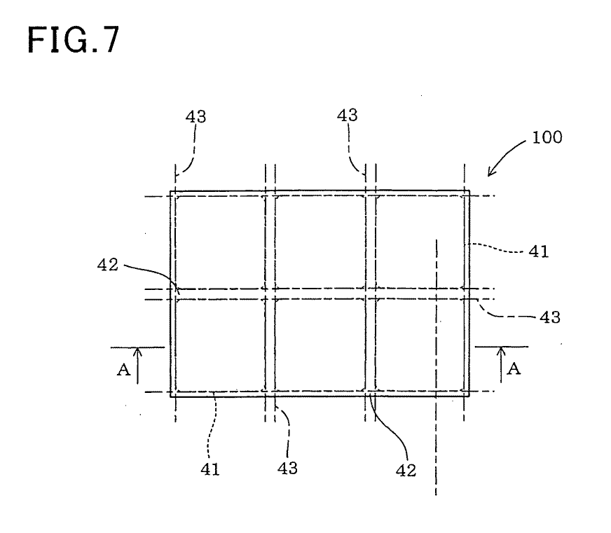

Next, the first electrode-printed sheet 31 and the second electrode-printed sheet 32, and the burn-off slit-printed sheets 33 were, as illustrated in FIG. 7, stacked in a given order so as to align the printing areas 41 in the laminating direction. Specifically, the first electrode-printed sheets 31 and the second electrode-printed sheets 32 were stacked alternately. Each of the burn-off slit-printed sheets 33 was inserted into the location where the above described slits are desired to be formed. Specifically, in this embodiment, the burn-off slit-printed sheet 33 was stacked on every stack of eleven layers made up of the first electrode-printed sheets 31 and the second electrode-printed sheets 32. The first electrode-printed sheets 31 and the second electrode-printed sheets 32 were stacked until a total number of them is 59.

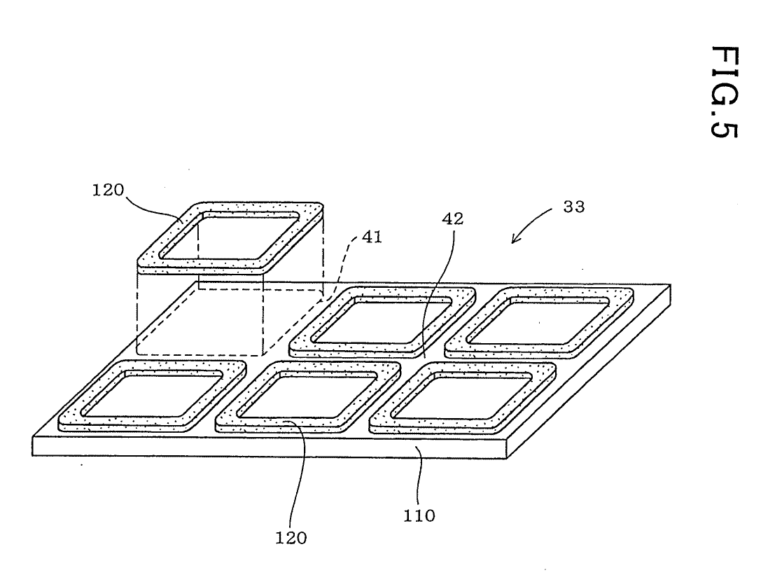

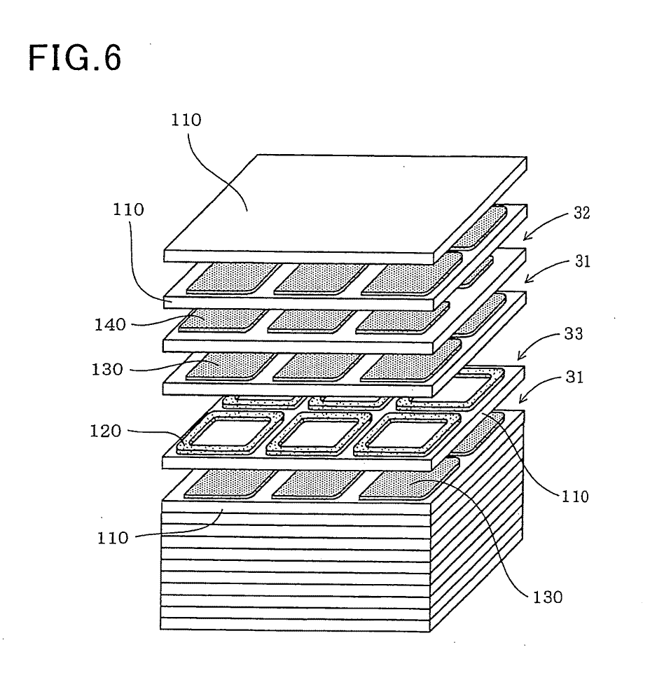

The first electrode-printed sheets 31 and the second electrode-printed sheets 32 were stacked so that the electrode material 130 and the electrode material 140 were exposed alternately to the end surface which the printing areas face. As two of the electrode-printed sheets interleaving the burn-off slit-printed sheet 33, printed-sheets (i.e., the first electrode-printed sheets 31) which were identical in pattern formed by the electrode material with each other were used. Specifically, as illustrated in FIG. 6, the first electrode-printed sheets 31 were placed above and below the burn-off slit-printed sheet 33 and oriented so as to expose the electrode materials 130, as printed after the following cutting process, to the same side surface.

The green sheet 110 not subjected to the printing process was disposed on an upper end of the sheets to be stacked.

The sheets stacked in this manner were heated at 100° C. and pressed at 50 MPa in the laminating direction to make a pre-stack 100. For the sake of convenience, FIG. 6 illustrates the pre-stack 100 which is smaller in number of stacked layers than actual.

<Stack Cutting Process>

Next, as illustrated in FIGS. 7 to 9, the pre-stack 100 was cut at the cutting positions 43 in the laminating direction to form the intermediate stacks 10.

The pre-stack 100 may be cut in the unit of the intermediate stacks 10 or in the unit of two or more of them. In this embodiment, the pre-stack 100 was cut in the unit of each of the intermediate stacks 10 so that each of the electrode materials 130 and 140 and the burn-off slit layers 120 were exposed to the side surfaces of the intermediate stack 10.

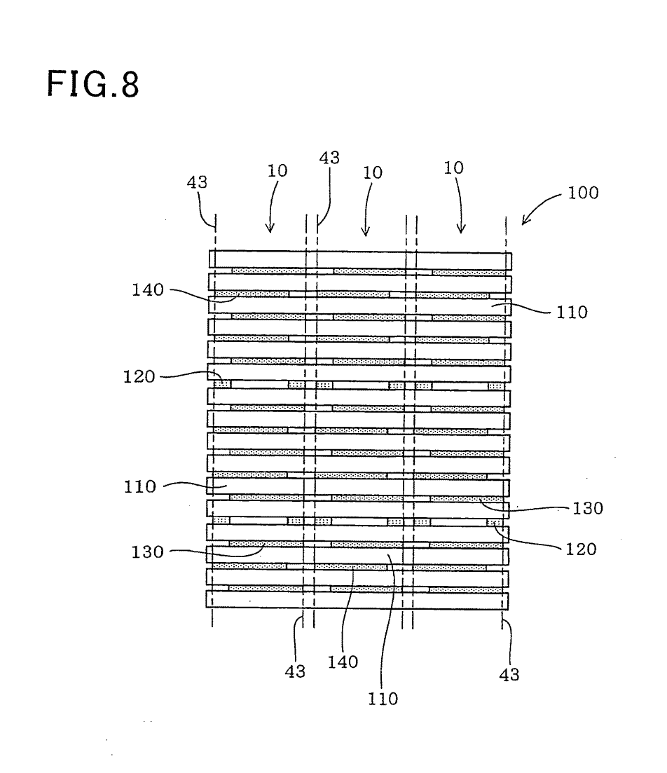

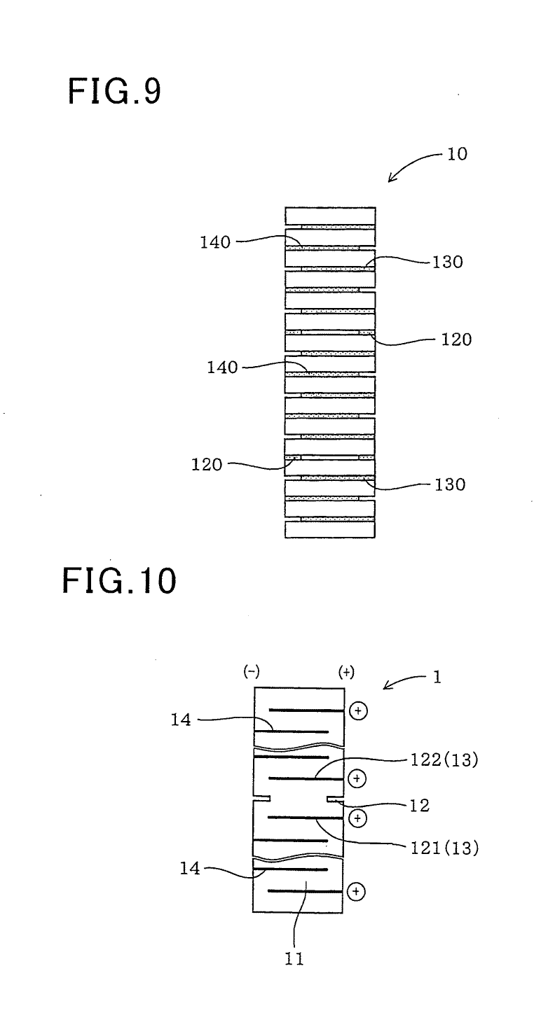

For the sake of convenience, FIGS. 8 and 9 illustrate the pre-stack 100 and the inter mediate stacks 10 which are smaller in number of stacked layers than actual.

<Firing Process>

Next, binder resin contained in the green sheet 110 of the intermediate stacks 10 was removed thermally (degreased) by 90% or more. This was achieved by heating the binder resin gradually up to 500° C. for eighty hours and keeping it for five hours.

Next, the degreased intermediate stacks 10 were fired. The firing was achieved by heating the intermediate stacks 10 gradually up to 1050° C. for twelve hours, keeping them for two hours, and then cooling them gradually.

In this manner, the ceramic laminate 15 is, as illustrated in FIGS. 1 and 2, made which has the stress absorbing portions 12 formed by the burning off of the burn-off slit layers 120. The stress absorbing portions 12 are defined by slit-like chambers formed in the entire circumferential surface of the ceramic laminate 15. As illustrated in FIGS. 1 and 2, the ceramic laminate 15 is made of the piezoelectric ceramic layers 11 formed by the sintered green sheets 110 and the inner electrode layers 13 and 14 formed by the electrode materials 130 and 140 which are stacked alternately.

After fired, the entire surface of the ceramic laminate 15 was polished to be 6 mm×6 mm square and 4.4 mm high. The side electrodes 17 and 18 were printed on the both side surfaces of the ceramic laminate 15. The inner electrodes 13 and 14 are connected electrically alternately to the side electrodes 17 and 18 respectively. Two of the inner electrode layers 121 and 122 interleaving the stress absorbing portion 12 therebetween are connected electrically to the side electrode 17. In this embodiment, the side electrode 17 to which the two inner electrode layers 121 and 123 interleaving the stress absorbing portion therebetween is a positive electrode.

In the above manner, the stacked piezoelectric device 1 was made which, as illustrated in FIGS. 1 and 2, includes the ceramic laminate 15 made by stacking the plurality of piezoelectric ceramic layers 11 and the plurality of inner electrode layers 13 and 14 alternately, the slit-like stress absorbing portions 12, and the pair of side electrodes 17 and 18 formed on the side surfaces of the ceramic laminate 15.

For the sake of convenience, FIGS. 1 and 2 illustrate the stacked piezoelectric device 1 which is smaller in number of stacked layers than actual. FIG. 2 also illustrates the stacked piezoelectric device 1 from which the side electrodes are omitted.

In this embodiment, the stacked piezoelectric device 1 (see FIG. 10) was made in the above production method in which adjacent two of the inner electrode layers 121 and 122 interleaving the slit-like groove (i.e., the stress absorbing portion) 12 therebetween are both connected electrically to the positive side of the side electrodes, and two of the inner electrode layers 13 which are located most outward in the laminating direction are connected electrically to the positive side of the side electrodes. This will be referred to as a sample E1.

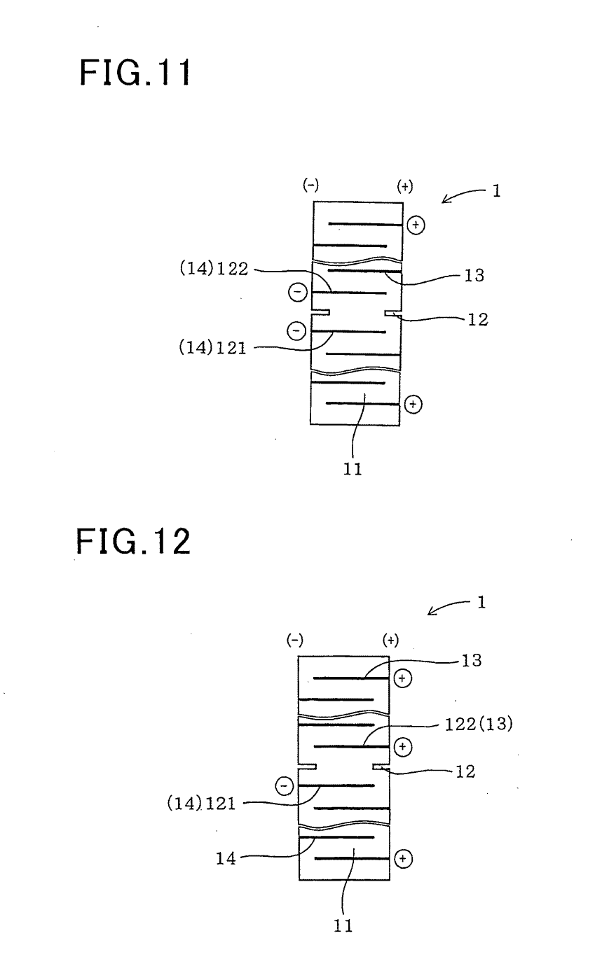

As a comparison with the sample E1, the stacked piezoelectric device 1 (see FIG. 11) was made in which adjacent two of the inner electrode layers 121 and 122 interleaving the slit-like groove (i.e., the stress absorbing portion) 12 therebetween are respectively connected electrically to the negative side of the side electrodes, and two of the inner electrode layers 13 which are located most outward in the laminating direction are, like in the sample E1, connected electrically to the positive side of the side electrodes. This will be referred to as a sample Ca1.

As a comparison with the sample E1, the stacked piezoelectric device 1 (see FIG. 12) was made in which adjacent two of the inner electrode layers 121 and 122 interleaving the slit-like groove (i.e., the stress absorbing portion) 12 therebetween are respectively connected electrically to the different side electrodes, and two of the inner electrode layers 13 which are located most outward in the laminating direction are, like in the sample E1, connected electrically to the positive side of the side electrodes. This will be referred to as a sample Cb1.

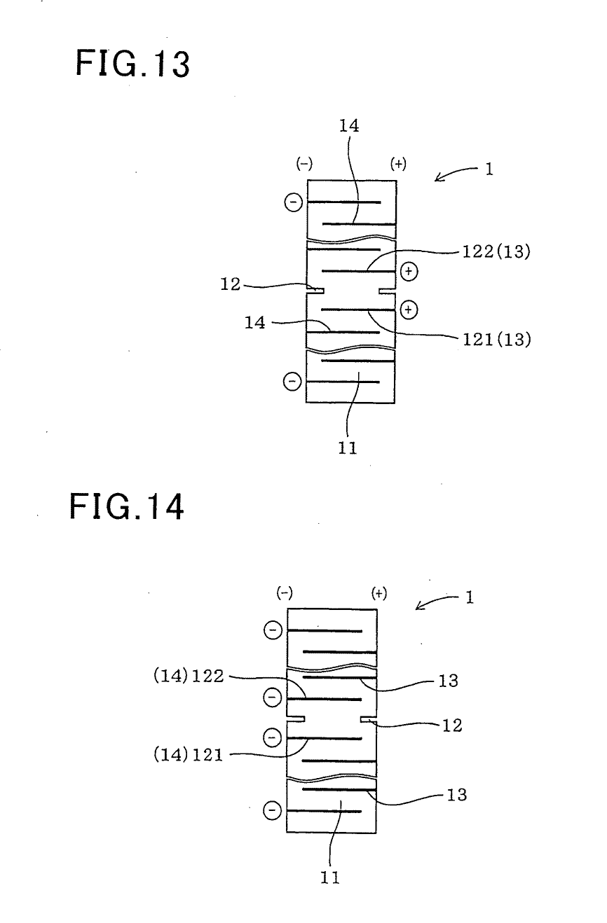

Additionally, in this embodiment, the stacked piezoelectric device 1 (see FIG. 13) was made in the same production method, as described above, in which adjacent two of the inner electrode layers 121 and 122 interleaving the slit-like groove (i.e., the stress absorbing portion) 12 therebetween are both connected electrically to the positive side of the side electrodes, and two of the inner electrode layers 13 which are located most outward in the laminating direction are connected electrically to the negative side of the side electrodes. This will be referred to as a sample E2.

As a comparison with the sample E2, the stacked piezoelectric device 1 (see FIG. 14) was made in which adjacent two of the inner electrode layers 121 and 122 interleaving the slit-like groove (i.e., the stress absorbing portion) 12 therebetween are respectively connected electrically to the negative side of the side electrodes, and two of the inner electrode layers 13 which are located most outward in the laminating direction are, like in the sample E2, connected electrically to the negative side of the side electrodes. This will be referred to as a sample Ca2.

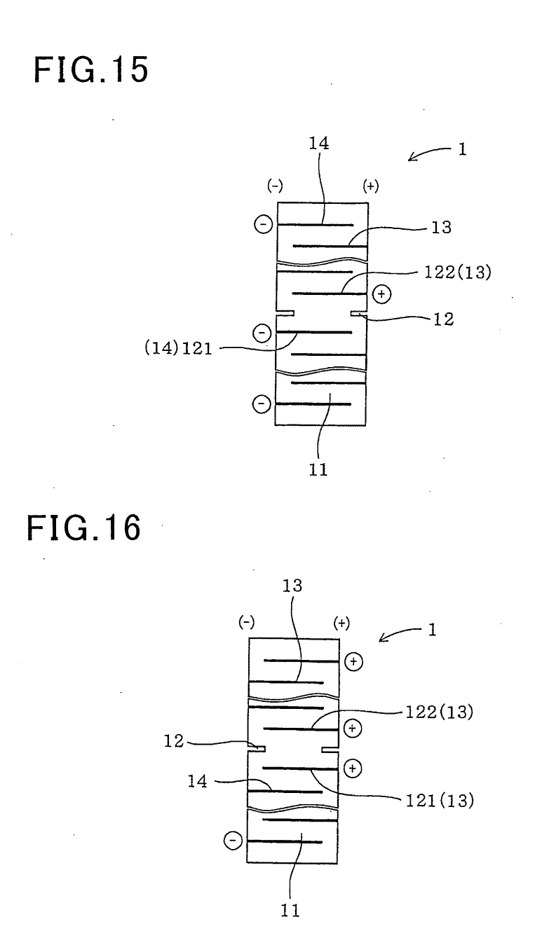

As a comparison with the sample E2, the stacked piezoelectric device 1 (see FIG. 15) was made in which adjacent two of the inner electrode layers 121 and 122 interleaving the slit-like groove (i.e., the stress absorbing portion) 12 therebetween are respectively connected electrically to the different side electrodes, and two of the inner electrode layers 13 which are located most outward in the laminating direction are, like in the sample E2, connected electrically to the negative side of the side electrodes. This will be referred to as a sample Cb2.

Further, in this embodiment, the stacked piezoelectric device 1 (see FIG. 16) was made in the above production method in which adjacent two of the inner electrode layers 121 and 122 interleaving the slit-like groove (i.e., the stress absorbing portion) 12 therebetween are both connected electrically to the positive side of the side electrodes, and two of the inner electrode layers 13 which are located most outward in the laminating direction are respectively connected electrically to the different side electrodes. This will be referred to as a sample E3.

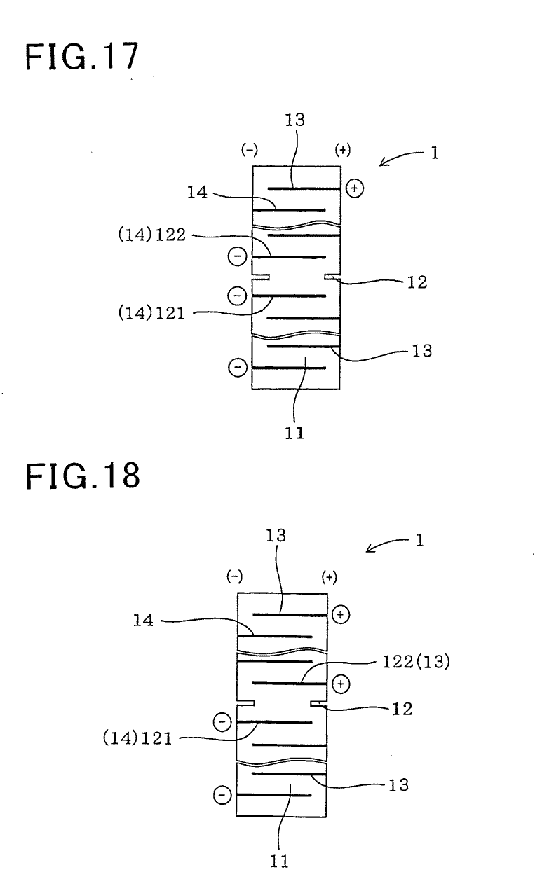

As a comparison with the sample E3, the stacked piezoelectric device 1 (see FIG. 17) was made in which adjacent two of the inner electrode layers 121 and 122 interleaving the slit-like groove (i.e., the stress absorbing portion) 12 therebetween are respectively connected electrically to the negative side of the side electrodes, and two of the inner electrode layers 13 which are located most outward in the laminating direction are, like in the sample E3, connected electrically to the different side electrodes. This will be referred to as a sample Ca3.

As a comparison with the sample E3, the stacked piezoelectric device 1 (see FIG. 18) was made in which adjacent two of the inner electrode layers 121 and 122 interleaving the slit-like groove (i.e., the stress absorbing portion) 12 therebetween are respectively connected electrically to the different side electrodes, and two of the inner electrode layers 13 which are located most outward in the laminating direction are, like in the sample E3, connected electrically to the different side electrodes, respectively. This will be referred to as a sample Cb3.

For the sake of convenience, FIGS. 10 to 18 illustrate the stacked piezoelectric devices 1 which are smaller in number of stacked layers and outer electrodes than actual.

We performed the following durability tests on the stacked piezoelectric device (i.e., the samples E1 to E3, Ca1 to Ca3, and Cb1 to Cb3, as made in the above.

<Durability Test>

We applied an electric field of 3.1 kV/mm to the stacked piezoelectric device of each sample at 200° C. to drive it. We connected each sample to a resistor R whose resistance value was known in parallel thereto to develop a circuit. We read the voltage (leakage current value) applied to the resistor R through a digital meter while applying the electric field to each sample. We measured the time elapsed until the insulation resistance of the device (sample) drops below 10 MΩ and defines it as the service life of the device. The durability tests were performed on the five samples of each of the above types.

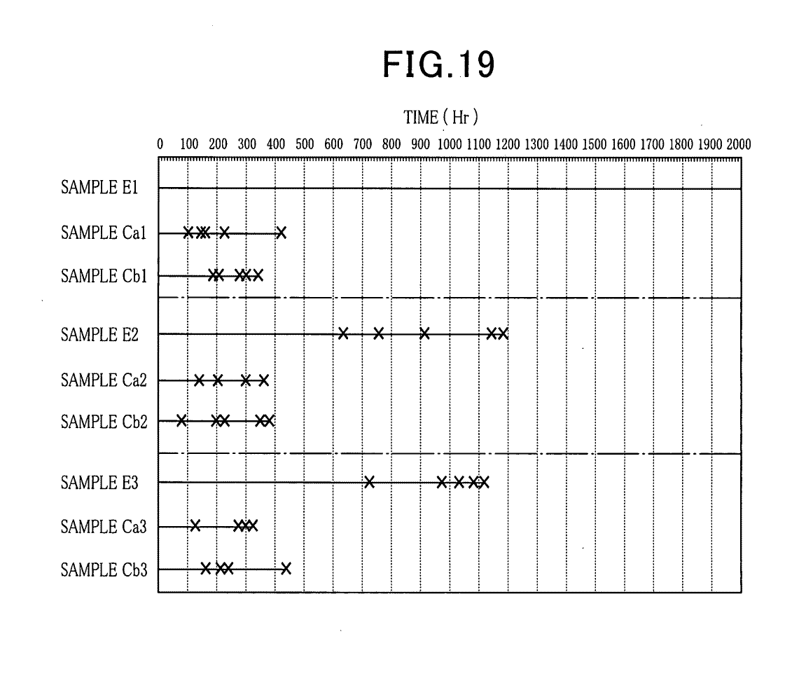

The results are shown in FIG. 19. In FIG. 19, the abscissa axis indicates the time elapsed from application of electric field. The time when the insulation resistance has dropped below 10 MΩ is expressed by “X”.

FIG. 19 shows that the stacked piezoelectric devices 1 of the samples E1 to E3 (see FIGS. 10, 13, and 16) in which adjacent two of the inner electrode layers 121 and 122 interleaving the stress absorbing portion 12 therebetween are both connected electrically to the positive side of the side electrodes show excellent durability greater than at least 600 hours.

It is found that especially, in the case where two of the inner electrode layers 13 which are located most outward in the laminating direction of the ceramic laminate are, like the sample E1, connected electrically to the positive side of the side electrodes (see FIG. 10), there is no one of the five samples in which the insulation resistance drops below 10 MΩ after operation for a long term of 2,000 h.

It is found that in the case where two of the inner electrode layers 13 which are located most outward in the laminating direction of the ceramic laminate are, like the sample E2, connected electrically to the negative side of the side electrodes (see FIG. 13), there are some of the samples which show an excellent durability of at least 600 h or more or as high as 1100 h or more.

It is found that in the case where two of the inner electrode layers 13 which are located most outward in the laminating direction of the ceramic laminate, like the sample E3, are connected electrically to the different side electrodes, respectively (see FIG. 16), there are some of the samples which show an excellent durability of at least 700 h or more or about 1100 h.

In contrast to the above, it is found that the stacked piezoelectric devices 1 (i.e., the samples Cb1 to Cb3), as illustrated in FIGS. 11, 14, and 17, in which adjacent two of the inner electrode layers 121 and 122 interleaving the stress absorbing portion 12 therebetween are both connected electrically to the negative side of the side electrodes are lower in insulation resistance than 10 MΩ when actuated for at most 450 h and show insufficient durability.

As described above, the invention avoids the drop in insulation resistance surely and enables the stacked piezoelectric devices (i.e., the sample E1 to E3) which are excellent in the durability.

In this embodiment, the stress absorbing portions are formed using the burn-off material which will burn off in the firing process, but however, they alternatively be formed by material (crack material) which will be cracked when being polarized or actuated.

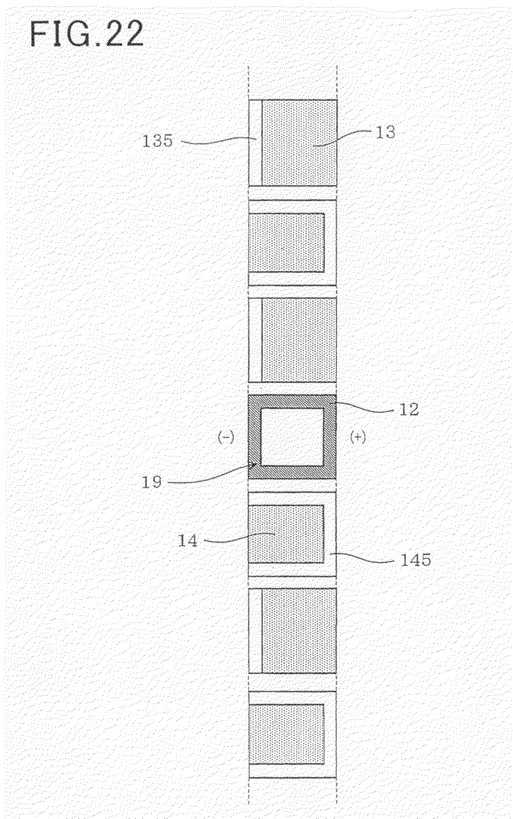

In this embodiment, the inner electrode layers 131 and 141, the recessed portions 135 and 145, and the slit layers 12 are formed in the combination pattern, as illustrated in FIG. 22. The invention is not limited to such a pattern. When seen therethrough in the laminating direction, the ceramic laminate has overlapping portions that are areas where all the inner electrode portions overlap each other and non-overlapping portions that are areas where the inner electrode portions at least partially overlap each other or do not overlap at all. The stress absorbing portions may be formed in the non-overlapping portions 19.

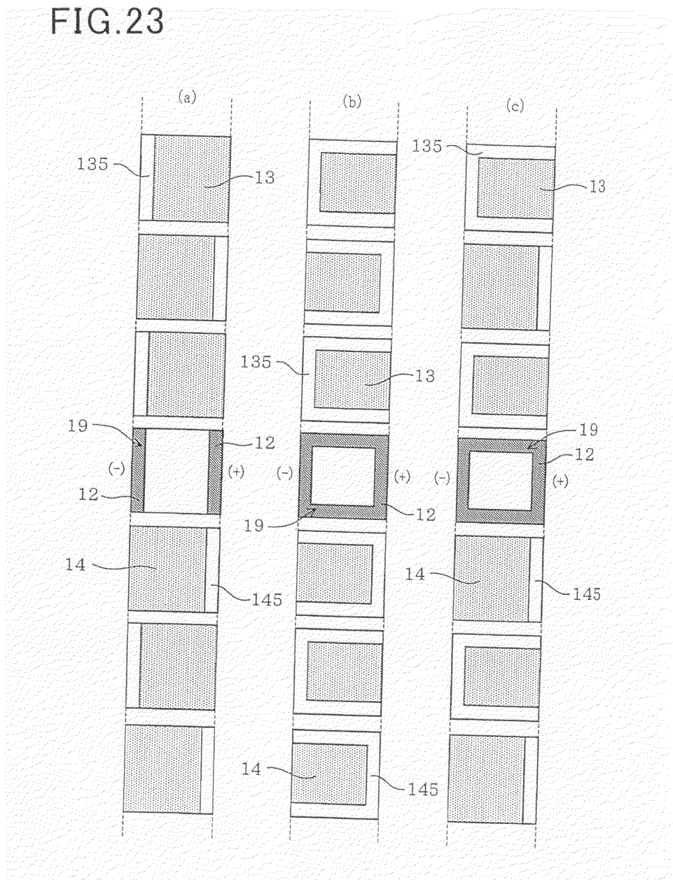

Possible combinations of the inner electrode portions 131 and 141 and the slit layers 12 are demonstrated in FIGS. 23(a) to 23(c). Any of the combinations offers sufficient effects of the invention.

1. A stacked piezoelectric device including a ceramic laminate formed by laminating a plurality of piezoelectric ceramic layers and a plurality of inner electrode layers alternately and a pair of side electrodes formed on side surfaces of the ceramic laminate, characterized in that
said inner electrode layers are connected electrically to either of the side electrodes,
said ceramic laminate has stress absorbing portions formed in slit-like areas recessed inwardly from the side surfaces thereof, the stress absorbing portions being easier to deform than said piezoelectric ceramic layers, and
adjacent two of said inner electrode layers interleaving the stress absorbing portion therebetween are both connected electrically to a positive side of the side electrodes.

2. A stacked piezoelectric device as set forth in claim 1, characterized in that the stress absorbing portions are slit-like grooves recessed inwardly from the side surface of the ceramic laminate,

3. A stacked piezoelectric device as set forth in claim 1, characterized in that the stacked piezoelectric device is made by firing the plurality of piezoelectric ceramic layers and the plurality of inner electrode layers integrally.

4. A stacked piezoelectric device as set forth in claim 1, characterized in that said stacked piezoelectric device is made by bonding a plurality of the ceramic laminates through adhesive in a laminating direction.

5. A stacked piezoelectric device as set forth in claim 4, characterized in that the stress absorbing portions are formed by providing non-bonding portions to which no adhesive is applied near an outer periphery of said ceramic laminates when the ceramic laminates are joined together with the adhesive.

6. A stacked piezoelectric device as set forth in claim 1, characterized in that the stress absorbing portions are made using burn-off material which will burn off when being fired.

7. A stacked piezoelectric device as set forth in claim 1, characterized in that the stress absorbing portions are made by forming said slit-like areas by material which causes cracks to occur when said stacked piezoelectric device is polarized or actuated and cracking the slit-like areas when said stacked piezoelectric device is polarized or actuated.

8. A stacked piezoelectric device as set forth in claim 1, characterized in that two of the inner electrode layers which are located most outward of the stacked piezoelectric device in a laminating direction are both connected to a positive side of the side electrodes.

9. A stacked piezoelectric device as set forth in claim 1, characterized in that the stacked piezoelectric device is used in a fuel injector.
